(19) United States
(12) Patent Application Publication
(10) Pub. No.: US 2018/0211598 A1
(43) Pub. Date: Jul. 26, 2018

(54) ORGANIC DIODE DISPLAY DRIVING CIRCUITS, DISPLAY PANELS AND ELECTRONIC DEVICES

(71) Applicant: Wuhan China Star Optoelectronics Technology Co., Ltd., Wuhan, Hubei (CN)

(72) Inventor: Shijuan YI, Shenzhen, Guangdong (CN)

(73) Assignee: Wuhan China Star Optoelectronics Technology Co., L td., Wuhan, Hubei (CN)

(21) Appl. No.: 15/319,772

(22) PCT Filed: Dec. 2, 2016
(86) PCT No.: PCT/CN2016/108335

§ 371 Date: Dec. 17, 2016

(30) Foreign Application Priority Data
Aug. 22, 2016 (CN) 2016107010287

(51) Int. Cl. G09G 3/3258; H01L 27/32; H01L 51/56

(52) U.S. Cl. CPC G09G 3/3258; H01L 27/3276; G09G 2300/02; G09G 2300/0809; H01L 51/56

(57) ABSTRACT

The present disclosure relates to an organic diode display driving circuit, a display panel, and an electronic device. The driving circuit includes a voltage source, a display-area circuit, and an auxiliary-area circuit being arranged outside a display area. The display-area circuit and the auxiliary-area circuit include power-supply wirings, signal wirings, and at least one pixel, and the voltage source connects to the pixel within the display area via the power-supply wirings. The voltage source further directly or indirectly connects to the pixel within the display area via the wirings in an auxiliary area. By configuring the wirings in the auxiliary area to connect to the voltage line, the resistance of the power-supply wirings in the display area may be reduced so as to eliminate the voltage drop of the power-supply wirings in the display area.

### BACKGROUND OF THE INVENTION

### 1. Field of the Invention

The present disclosure relates to liquid crystal display technology, and more particularly to an organic diode display driving circuit, a display panel, and an electronic device.

### 2. Discussion of the Related Art

Active matrix organic light-emitting diode (OLED) panels generally includes very thin organic coating layers and a glass substrate. When the current passes by, the organic material emits light. The OLED panels are characterized by self-light-emitting, wide viewing angle, and high saturation. In particular, the driving voltage is low and the power consumption is low. In addition, the OLED panels also have the advantages such as quick response time, light weight, thin thickness, simple structure, and low lost, and thus have been deemed as the most potential product.

OLED panels include a normal pixel area (AA pixel area) and a virtual pixel area. The virtual pixel area is designed to alleviate the loading effect during the manufacturing process of the matrix substrate so as to enhance the uniformity of the high-precision metallic masking plate during evaporation processes. In regard to pixel compensation circuits, generally, the signals lines within the pixel area circuit are connected with a fixed level such that the thin film transistors (TFTs) are turned off and the virtual pixel area is in a dark state.

However, as the distances between each of the pixels within the AA pixel area and the pixel source are different, which results in that the voltage drops caused by the wirings are different. Thus, the display uniformity of the panel may be affected.

### SUMMARY

The present disclosure relates to an organic diode display driving circuit, a display panel, and an electronic device for enhancing the display uniformity of the panels.

In one aspect, an organic diode display driving circuit includes: a voltage source, a display-area circuit, and an auxiliary-area circuit being arranged outside a display area; the display-area circuit and the auxiliary-area circuit include power-supply wirings, signal wirings, and at least one pixel, and the voltage source connects to the pixel within the display area via the power-supply wirings; and the voltage source further directly or indirectly connects to the pixel within the display area via the wirings in an auxiliary area.

Wherein the voltage source directly or indirectly to the pixel in the display area via the signal wirings in the auxiliary area.

Wherein the signal wirings in the auxiliary area includes one of or a combination comprising some of the scanning lines, an initial-voltage line, a light-emitting control line and a data line.

Wherein the power-supply wirings include row power-supply lines and column power-supply lines arranged along rows and columns, and the column power-supply lines and the row power-supply lines are connected, the column power-supply lines and the row power-supply lines connect to the voltage source; and the scanning lines, the initial voltage line, and the light-emitting control line in the auxiliary area respectively connect to the two voltage lines in the auxiliary area such that the voltage source indirectly connects to the pixel in the display area via the wirings in the auxiliary area.

Wherein the data lines are arranged along the columns, one end of the data line connects to the voltage line, and the other end connects to the other voltage line, and/or the other end of the data line connects to the row power-supply line on a different layer via a contact hole.

Wherein the power-supply wirings include row power-supply lines and column power-supply lines arranged along rows and columns, and the column power-supply lines and the row power-supply lines are connected; and the scanning lines, the initial voltage line, and/or the light-emitting control line in the auxiliary area connect to the row power-supply line on the different layer via a contact hole such that the voltage source indirectly connects to the pixel in the display area via the wirings in the auxiliary area.

Wherein the circuit further includes the voltage line arranged at one side of the display area, the voltage source connects to the voltage line, and one end of the column power-supply line or the row power-supply line connects to the voltage line; the scanning lines in the auxiliary area, a vi line, an EM line connects directly or indirectly to the column power-supply lines on different layers further include: the scanning lines, the initial voltage line, the light-emitting control line on the first layer, and the column power-supply line are connected, and the data lines on the second layer are connected with the row power-supply line, at the same time, the column power-supply lines and the row power-supply lines on different layers are connected via at least one contact hole such that the voltage source indirectly connects to the pixel in the display area via the signal wirings in the auxiliary area.

Wherein the scanning lines, the initial voltage line, and the light-emitting control line respectively connect to the voltage line.

In another aspect, a display panel includes: an organic diode display driving circuit includes: a voltage source, a display-area circuit, and an auxiliary-area circuit being arranged outside a display area; the display-area circuit and the auxiliary-area circuit include power-supply wirings, signal wirings, and at least one pixel, and the voltage source connects to the pixel within the display area via the power-supply wirings; and the voltage source further directly or indirectly connects to the pixel within the display area via the wirings in an auxiliary area.

Wherein the voltage source directly or indirectly to the pixel in the display area via the signal wirings in the auxiliary area.

Wherein the signal wirings in the auxiliary area includes one of or a combination of some of the scanning lines, an initial-voltage line, a light-emitting control line and a data line.

Wherein the power-supply wirings include row power-supply lines and column power-supply lines arranged along rows and columns, and the column power-supply lines and the row power-supply lines are connected, the column power-supply lines and the row power-supply lines connect to the voltage source; and the scanning lines, the initial voltage line, and the light-emitting control line in the auxiliary area respectively connect to the two voltage lines in the auxiliary area such that the voltage source indirectly connects to the pixel in the display area via the wirings in the auxiliary area.

Wherein the data lines are arranged along the columns, one end of the data line connects to the voltage line, and the other end connects to the other voltage line, and/or the other end of the data line connects to the row power-supply line on a different layer via a contact hole.

Wherein the power-supply wirings include row power-supply lines and column power-supply lines arranged along rows and columns, and the column power-supply lines and the row power-supply lines are connected; and the scanning lines, the initial voltage line, and/or the light-emitting control line in the auxiliary area connect to the row power-supply line on the different layer via a contact hole such that the voltage source indirectly connects to the pixel in the display area via the wirings in the auxiliary area.

Wherein the circuit further includes the voltage line arranged at one side of the display area, the voltage source connects to the voltage line, and one end of the column power-supply line or the row power-supply line connects to the voltage line; the scanning lines in the auxiliary area, a vi line, an EM line connects directly or indirectly to the column power-supply lines on different layers further include: the scanning lines, the initial voltage line, the light-emitting control line on the first layer, and the column power-supply line are connected, and the data lines on the second layer are connected with the row power-supply line, at the same time, the column power-supply lines and the row power-supply lines on different layers are connected via at least one contact hole such that the voltage source indirectly connects to the pixel in the display area via the signal wirings in the auxiliary area.

In another aspect, an electronic device includes: a display device comprising an organic diode display driving circuit, the organic diode display driving circuit includes: a voltage source, a display-area circuit, and an auxiliary-area circuit being arranged outside a display area; the display-area circuit and the auxiliary-area circuit include power-supply wirings, signal wirings, and at least one pixel, and the voltage source connects to the pixel within the display area via the power-supply wirings; and the voltage source further directly or indirectly connects to the pixel within the display area via the wirings in an auxiliary area.

Wherein the voltage source directly or indirectly to the pixel in the display area via the signal wirings in the auxiliary area.

Wherein the signal wirings in the auxiliary area includes one of or a combination comprising some of the scanning lines, an initial-voltage line, a light-emitting control line and a data line.

Wherein the power-supply wirings include row power-supply lines and column power-supply lines arranged along rows and columns, and the column power-supply lines and the row power-supply lines are connected, the column power-supply lines and the row power-supply lines connect to the voltage source; and the scanning lines, the initial voltage line, and the light-emitting control line in the auxiliary area respectively connect to the two voltage lines in the auxiliary area such that the voltage source indirectly connects to the pixel in the display area via the wirings in the auxiliary area.

Wherein the data lines are arranged along the columns, one end of the data line connects to the voltage line, and the other end connects to the other voltage line, and/or the other end of the data line connects to the row power-supply line on a different layer via a contact hole.

By configuring the wirings in the auxiliary area to connect to the voltage line, the resistance of the power-supply wirings in the display area may be reduced so as to eliminate the voltage drop of the power-supply wirings in the display area.

### BRIEF DESCRIPTION OF THE DRAWINGS

FIG. 1 is a schematic view of the organic diode display driving circuit in accordance with a first embodiment.

FIG. 2 is a schematic view of the organic diode display driving circuit in accordance with a second embodiment.

FIG. 3 is an enlarged view of the pixel in an auxiliary area of the organic diode display driving circuit in accordance with the second embodiment.

FIG. 4 is a schematic view of the display panel in accordance with one embodiment.

FIG. 5 is a schematic view of the electronic device in accordance with one embodiment.

### DETAILED DESCRIPTION OF THE EMBODIMENTS

Embodiments of the invention will now be described more fully hereinafter with reference to the accompanying drawings, in which embodiments of the invention are shown.

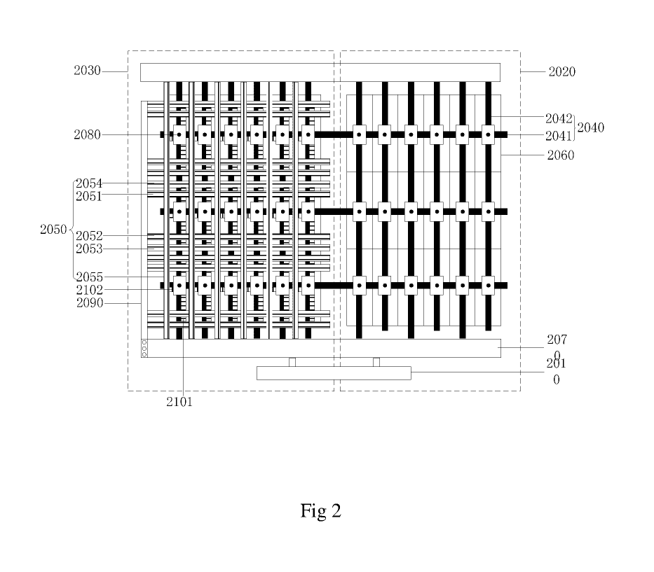

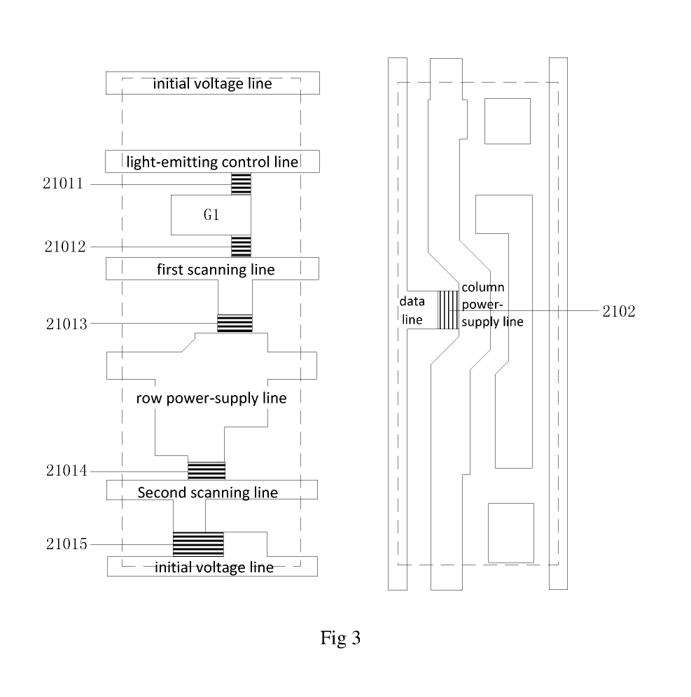

FIG. 2 is a schematic view of the organic diode display driving circuit in accordance with a second embodiment. FIG. 3 is an enlarged view of the pixel in an auxiliary area of the organic diode display driving circuit in accordance with the second embodiment. As shown in FIG. 2, the flat display device 20 includes a backlight system 21 and a display panel 22. The backlight system 21 is arranged at a back side of the display panel 22 to provide a light source for the display panel 22.

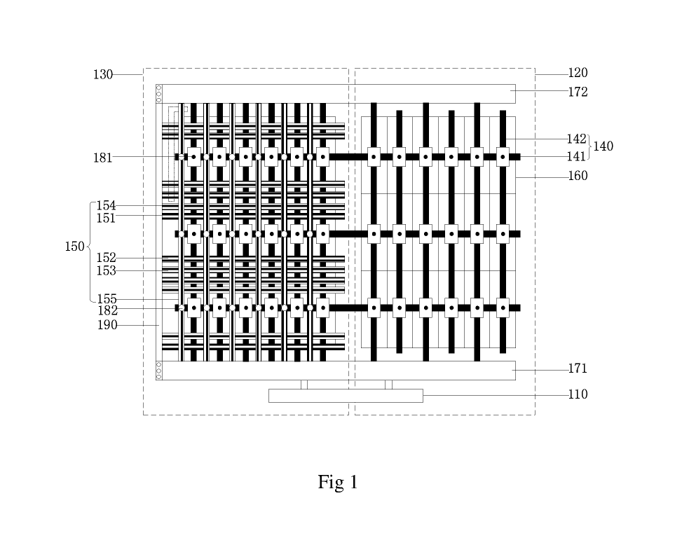

FIG. 1 is a schematic view of the organic diode display driving circuit in accordance with a first embodiment. The organic diode display driving circuit includes a voltage source 110, a display-area circuit 120, and an auxiliary-area circuit 130 arranged outside a display area. The voltage source 110 provides the voltage to the whole chip, the display-area circuit 120 and the auxiliary-area circuit 130 include power-supply wirings 140, signal wirings 150, and at least one pixel 160. The voltage source 110 connects to the pixel 160 within the display area via the power-supply wirings 140. The voltage source 110 further directly or indirectly connects to the pixel 160 within the display area via the signal wirings 150 in the auxiliary area.

Specifically, the signal wirings 150 in the auxiliary area includes one of or a combination including some of the first scanning line 151, a second scanning line 152, an initial-voltage line 153, a light-emitting control line 154 and a data line 155.

The power-supply wirings 140 include row power-supply lines 142 and column power-supply lines 141 arranged along the rows and the columns, and the column power-supply lines 141 and the row power-supply lines 142 are connected. In addition, the column power-supply lines 141 and the row power-supply lines 142 connect to the voltage source 110, wherein the column power-supply lines 141 and the row power-supply lines 142 are connected by a first contact hole 181.

The first scanning line 151, the second scanning line 152, the initial-voltage line 153, the light-emitting control line 154 are arranged at a first layer of the chip, that is, are on the same layer with the column power-supply lines 141. The data line 155 is arranged at a second layer of the chip, that is, on the same layer with the row power-supply lines 142.

In the embodiment, one wide wirings 190 is arranged at a left side of the auxiliary area for connecting ends of the first scanning line 151, the second scanning line 152, the initial-voltage line 153, and the light-emitting control line 154 to a voltage line 171 such that the voltage source 110 may be indirectly connected with the pixel 160 in the display area via the wirings in the auxiliary area, including the first scanning line 151, the second scanning line 152, the initial-voltage line 153, the light-emitting control line 154, and the data line 155.

Further, the data line 155 are arranged along a column direction, wherein one end of the data line 155 connects to one voltage line 171, and the other end of the data line 155 connects to another voltage line 172, and/or the other end of the data line 155 connects to the power-supply wirings 140 on different layers via a second contact hole 182.

Taking the display area and the auxiliary area in the lower left portion as one example, one end of the signal wirings 150 connects to one voltage line 171, and the other end of the signal wirings 150 connects to another voltage line 172. The voltage source 110 provides a certain voltage to the pixel 160 in the display area via the signal wirings 150 and two voltage lines in the auxiliary area, and the power-supply wirings in the display area. In this way, the serious voltage-drop issue of the pixel 160 in the display area caused by the wirings may be eliminated so as to enhance the uniformity of the display panel.

It can be understood that the data line 155 may not be connected to the voltage lines or the power-supply wirings 140. The voltage source 110 connects to the pixel 160 within the display area directly or indirectly via the signal wirings 150 other than the data line 155 within the auxiliary area. Alternatively, the voltage source 110 connects directly or indirectly to the pixel 160 via the data line 155 within the auxiliary area.

FIGS. 2 and 3 are directed to the organic diode display driving circuit in accordance with a second embodiment. The organic diode display driving circuit includes a voltage source 2010, a display-area circuit 2020, and an auxiliary-are circuit 2030, and the auxiliary area is outside of the display area. The display-area circuit 2020 and the auxiliary-are circuit 2030 both include power-supply wirings 2040, signal wirings 2050, and a pixel 2060. The voltage source 2010 connects to the pixel 2060 within the display area. The voltage source 2010 further directly or indirectly connects to the pixel 2060 within the display area via the signal wirings 2050 in the auxiliary area.

The signal wirings 2050 include one of or a combination of some of the first scanning line 2051, a second scanning line 2052, an initial voltage line 2053, a light-emitting control ling 2054 and the data line 2055.

The power-supply wirings 2040 include row power-supply lines 2041 and column power-supply lines 2042 arranged along the rows and the columns, and the row power-supply lines 2041 and the column power-supply lines 2042 are connected.

The signal wirings 2050 within the auxiliary area directly connect to the power-supply wirings 2040 such that the voltage source indirectly connects to the pixel 2060 within the display area via the wirings within the auxiliary area, such as the first scanning line 2051, the second scanning line 2052, the initial voltage line 2053, the light-emitting control ling 2054, and the data line 2055.

The connections between the signal wirings 2050 in the auxiliary area and the power-supply wirings 2040 will be described hereinafter. In an example, the wirings 2101 having different line-widths may be configured between the first scanning line 2051, the second scanning line 2052, the initial voltage line 2053, the light-emitting control ling 2054 on the first layer, and the row power-supply lines 2041 such that the signal wirings are connected to the row power-supply lines 2041. One section of wirings 2102 is configured between the data line 2055 on the second layer and the column power-supply lines 2042 such that the data line 2055 on the second layer and the column power-supply lines 2042 are connected. At the same time, the row power-supply lines 2041 on the different layers connect to the column power-supply lines 2042 via a contact hole 2080.

As shown in FIG. 3, the wiring 21011 is configured between the light-emitting control ling 2054 and G1, the wiring 21012 is configured between the G1 and the first scanning line 2051, and the wiring 21013 is configured between the first scanning line 2051 and the row power-supply lines 2041 such that the light-emitting control ling 2054, the first scanning line 2051, and the row power-supply lines 2041 are connected. At the same time, the wiring 21015 is configured between the initial voltage line 2053 and the second scanning line 2052, and the wiring 21014 is configured between the second scanning line 2052 and the row power-supply lines 2041 such that the initial voltage line 2053 and the second scanning line 2052 are connected with the row power-supply lines 2041. Similarly, the wiring 2102 is configured between the data line 2055 and the column power-supply lines 2042 such that the data line 2055 is connected with the column power-supply lines 2042.

The voltage line is arranged at one side of the display area. The voltage source 2010 connects to the voltage line 2070, and one end of the row power-supply lines 2041 or the column power-supply lines 2042 connects to the voltage line 2070.

Taking the display area and the auxiliary area in the lower left portion as one example, the signal wirings 2050 in the auxiliary area connect to the voltage line 2070. When the circuit is connected, the first scanning line 2051, the second scanning line 2052, the initial voltage line 2053, the light-emitting control ling 2054 in the auxiliary area connect to the row power-supply lines 2041 so as to supply the pixel 2060. The data line 2055 connects to the column power-supply lines 2042, and the column power-supply lines 2042 connects to the row power-supply lines 2041 to supply to the pixel 2060 in the display area. In this way, the serious voltage drop issue with respect to the wirings in the display area may be eliminated so as to enhance the display uniformity of the panel.

In other embodiment, wide wirings 2090 may be configured.

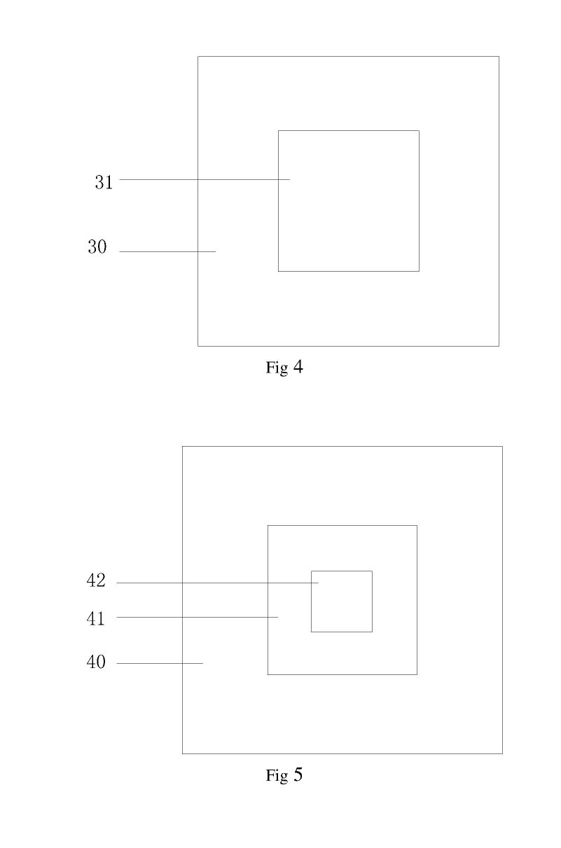

FIG. 4 is a schematic view of the display panel in accordance with one embodiment. As shown in FIG. 3, the display panel 30 includes an organic diode display driving circuit 31.

The organic diode display driving circuit 31 may include the configuration in FIG. 1 or 2.

After the display panel 30 is electrified, the pixels in the display area in the organic diode display driving circuit 31 emit lights via the power-supply wirings. At the same time, as the signal wirings are adopted to supplement the voltage consumed by the wirings in the display area toward the pixels in the display area, the display uniformity of the display panel 30 may be enhanced.

FIG. 5 is a schematic view of the electronic device in accordance with one embodiment. As shown, the electronic device 40 includes a display panel 41 adopting the organic diode display driving circuit 42. The organic diode display driving circuit 42 may include the configuration in FIG. 1 or 2, and the display panel may include the configuration in FIG. 3.

After the electronic device is electrified, the pixels in the display area emit lights via the operations of the organic diode display driving circuit 42 such that the display performance of the display panel 41 may be enhanced.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An organic diode display driving circuit, comprising:
a voltage source, a display-area circuit, and an auxiliary-area circuit being arranged outside a display area;
the display-area circuit and the auxiliary-area circuit comprise power-supply wirings, signal wirings, and at least one pixel, and the voltage source connects to the pixel within the display area via the power-supply wirings; and
the voltage source further directly or indirectly connects to the pixel within the display area via the wirings in an auxiliary area.

2. The circuit as claimed in claim 1, wherein the voltage source directly or indirectly to the pixel in the display area via the signal wirings in the auxiliary area.

3. The circuit as claimed in claim 2, wherein the signal wirings in the auxiliary area comprises one of or a combination comprising some of the scanning lines, an initial-voltage line, a light-emitting control line and a data line.

4. The circuit as claimed in claim 3, wherein the power-supply wirings comprise row power-supply lines and column power-supply lines arranged along rows and columns, and the column power-supply lines and the row power-supply lines are connected, the column power-supply lines and the row power-supply lines connect to the voltage source; and
the scanning lines, the initial voltage line, and the light-emitting control line in the auxiliary area respectively connect to the two voltage lines in the auxiliary area such that the voltage source indirectly connects to the pixel in the display area via the wirings in the auxiliary area.

5. The circuit as claimed in claim 4, wherein the data lines are arranged along the columns, one end of the data line connects to the voltage line, and the other end connects to the other voltage line, and/or the other end of the data line connects to the row power-supply line on a different layer via a contact hole.

6. The circuit as claimed in claim 3, wherein the power-supply wirings comprise row power-supply lines and column power-supply lines arranged along rows and columns, and the column power-supply lines and the row power-supply lines are connected; and
the scanning lines, the initial voltage line, and/or the light-emitting control line in the auxiliary area connect to the row power-supply line on the different layer via a contact hole such that the voltage source indirectly connects to the pixel in the display area via the wirings in the auxiliary area.

7. The circuit as claimed in claim 6, wherein the circuit further comprises the voltage line arranged at one side of the display area, the voltage source connects to the voltage line, and one end of the column power-supply line or the row power-supply line connects to the voltage line;
the scanning lines in the auxiliary area, a vi line, an EM line connects directly or indirectly to the column power-supply lines on different layers further comprise:
the scanning lines, the initial voltage line, the light-emitting control line on the first layer, and the column power-supply line are connected, and the data lines on the second layer are connected with the row power-supply line, at the same time, the column power-supply lines and the row power-supply lines on different layers are connected via at least one contact hole such that the voltage source indirectly connects to the pixel in the display area via the signal wirings in the auxiliary area.

8. The circuit as claimed in claim 6, wherein the scanning lines, the initial voltage line, and the light-emitting control line respectively connect to the voltage line.

9. A display panel, comprising:
an organic diode display driving circuit comprises:
a voltage source, a display-area circuit, and an auxiliary-area circuit being arranged outside a display area;
the display-area circuit and the auxiliary-area circuit comprise power-supply wirings, signal wirings, and at least one pixel, and the voltage source connects to the pixel within the display area via the power-supply wirings; and
the voltage source further directly or indirectly connects to the pixel within the display area via the wirings in an auxiliary area.

10. The display panel as claimed in claim 9, wherein the voltage source directly or indirectly to the pixel in the display area via the signal wirings in the auxiliary area.

11. The display panel as claimed in claim 10, wherein the signal wirings in the auxiliary area comprises one of or a combination of some of the scanning lines, an initial-voltage line, a light-emitting control line and a data line.

12. The display panel as claimed in claim 11, wherein the power-supply wirings comprise row power-supply lines and column power-supply lines arranged along rows and columns, and the column power-supply lines and the row power-supply lines are connected, the column power-supply lines and the row power-supply lines connect to the voltage source; and
the scanning lines, the initial voltage line, and the light-emitting control line in the auxiliary area respectively connect to the two voltage lines in the auxiliary area such that the voltage source indirectly connects to the pixel in the display area via the wirings in the auxiliary area.

13. The display panel as claimed in claim 12, wherein the data lines are arranged along the columns, one end of the data line connects to the voltage line, and the other end connects to the other voltage line, and/or the other end of the data line connects to the row power-supply line on a different layer via a contact hole.

14. The display panel as claimed in claim 11, wherein the power-supply wirings comprise row power-supply lines and column power-supply lines arranged along rows and columns, and the column power-supply lines and the row power-supply lines are connected; and
the scanning lines, the initial voltage line, and/or the light-emitting control line in the auxiliary area connect to the row power-supply line on the different layer via a contact hole such that the voltage source indirectly connects to the pixel in the display area via the wirings in the auxiliary area.

15. The display panel as claimed in claim 14, wherein the circuit further comprises the voltage line arranged at one side of the display area, the voltage source connects to the voltage line, and one end of the column power-supply line or the row power-supply line connects to the voltage line;
the scanning lines in the auxiliary area, a vi line, an EM line connects directly or indirectly to the column power-supply lines on different layers further comprise:
the scanning lines, the initial voltage line, the light-emitting control line on the first layer, and the column power-supply line are connected, and the data lines on the second layer are connected with the row power-supply line, at the same time, the column power-supply lines and the row power-supply lines on different layers are connected via at least one contact hole such that the voltage source indirectly connects to the pixel in the display area via the signal wirings in the auxiliary area.

16. An electronic device, comprising:
a display device comprising an organic diode display driving circuit, the organic diode display driving circuit comprises:
a voltage source, a display-area circuit, and an auxiliary-area circuit being arranged outside a display area;
the display-area circuit and the auxiliary-area circuit comprise power-supply wirings, signal wirings, and at least one pixel, and the voltage source connects to the pixel within the display area via the power-supply wirings; and
the voltage source further directly or indirectly connects to the pixel within the display area via the wirings in an auxiliary area.

17. The electronic device as claimed in claim 16, wherein the voltage source directly or indirectly to the pixel in the display area via the signal wirings in the auxiliary area.

18. The electronic device as claimed in claim 17, wherein the signal wirings in the auxiliary area comprises one of or a combination comprising some of the scanning lines, an initial-voltage line, a light-emitting control line and a data line.

19. The electronic device as claimed in claim 18, wherein the power-supply wirings comprise row power-supply lines and column power-supply lines arranged along rows and columns, and the column power-supply lines and the row power-supply lines are connected, the column power-supply lines and the row power-supply lines connect to the voltage source; and
the scanning lines, the initial voltage line, and the light-emitting control line in the auxiliary area respectively connect to the two voltage lines in the auxiliary area such that the voltage source indirectly connects to the pixel in the display area via the wirings in the auxiliary area.

20. The electronic device as claimed in claim 19, wherein the data lines are arranged along the columns, one end of the data line connects to the voltage line, and the other end connects to the other voltage line, and/or the other end of the data line connects to the row power-supply line on a different layer via a contact hole.
